(19) United States
(12) Patent Application Publication
(10) Pub. No.: US 2025/0294924 A1
(43) Pub. Date: Sep. 18, 2025

(54) VERTICALLY STRUCTURED LED LIGHT-EMITTING CHIP AND LIGHT-EMITTING STRUCTURE

(71) Applicant: BEIJING CHARMWIN LIGHT MEDICAL TECHNOLOGY CO., LTD., Beijing (CN)

(72) Inventors: Yi LUO, Beijing (CN); Bin YI, Beijing (CN); Liu LIU, Beijing (CN)

(21) Appl. No.: 19/078,355

(22) Filed: Mar. 13, 2025

(30) Foreign Application Priority Data
Mar. 14, 2024 (CN) 202410293097.3

(51) Int. Cl. H10H 20/821; H10H 20/832; H10H 20/856

(52) U.S. Cl. CPC H10H 20/821; H10H 20/835; H10H 20/856

(57) ABSTRACT

The present application relates to a technical field of semiconductor chips, and in particular, to a vertically structured LED light-emitting chip and light-emitting structure, the LED light-emitting chip includes a substrate, a side of the substrate is provided with a plurality of filling grooves, a depth of each of the plurality of filling grooves is less than or equal to a thickness of the substrate, a reflective layer is formed on a peripheral wall and a bottom surface of each of the filling grooves; an epitaxial layer formed on a side of the substrate away from the filling grooves; and a conductive paste, at least provided in the plurality of filling grooves.

### CROSS-REFERENCE TO RELATED APPLICATION

This application claims the priority to Chinese patent application serial no. 202410293097.3, filed on Mar. 14, 2024. The entirety of Chinese patent application serial no. 202410293097.3 is hereby incorporated by reference herein and made a part of this specification.

### TECHNICAL FIELD

The present application relates to a technical field of semiconductor chips, and, in particular, to a vertically structured LED light-emitting chip and light-emitting structure.

### BACKGROUND

An LED can efficiently convert electrical energy into light energy, with advantages such as small size, long lifespan, low power consumption, high brightness, and ease of integration. Therefore, an LED chip has a wide range of applications in modern society, such as lighting, flat-panel displays, medical devices, etc.

It is necessary to form an electrical connection between a chip and a substrate during chip package. In a current vertically structured chip packaging, a common method is to use a conductive silver paste on a side of the chip facing the substrate for a curing process, and then attach the chip to a surface of the substrate. Since the conductive silver paste has low resistance and a certain degree of fluidity, when the chip is attached to the substrate, the conductive silver paste wets the surface of the substrate and diffuses between the substrate and the chip, achieving a large area of electrical connection. This connection method has advantages of uniform current and low resistance.

However, the above connection method has a problem of low light extraction efficiency for the LED chip, especially the LED chip in a red wavelength range. This is due to the conductive silver paste has a strong absorption capacity for red light. Light emitted by an epitaxial layer includes a portion that incidents from the chip and can be effectively utilized, and a portion that irradiates toward the substrate direction and greatly absorbed by the conductive silver paste, reducing an effective light extraction of the LED chip. In addition, heat may be generated in a process of light absorption by the conductive silver paste, resulting in thermal accumulation between the substrate and the LED chip. Therefore, there is a need for a structure that can enhance the light extraction efficiency of the LED chip.

### SUMMARY

In order to solve the above problems, the present application provides a vertically structured LED light-emitting chip.

The vertically structured LED light-emitting chip provided in the present application adopts the following technical solution:

The vertically structured LED light-emitting chip, including:
a substrate, wherein a side of the substrate is provided with a plurality of filling grooves, a depth of each of the plurality of filling grooves is less than or equal to a thickness of the substrate, and a reflective layer is formed on a peripheral wall and a bottom surface of each of the filling grooves;
an epitaxial layer formed on a side of the substrate away from the filling grooves; and
a conductive paste, at least provided in the plurality of filling grooves.

In summary, the present application includes at least one of the following beneficial technical effects:
1. In the process that the light from the epitaxial layer is transmitted to the side close to the substrate or the bracket, the light can be reflected by the reflective layer provided in each of the filling grooves and on the surface of the substrate, so that the light can be emitted in a direction away from the substrate or the bracket, which improves the light utilization efficiency and enhances the light emitting intensity of the LED chip.
2. The conductive paste is provided in the filling grooves, which increases bonding area between the conductive paste and the substrate, enhances curing strength of the conductive paste and the substrate. When the chip is in use, the substrate only needs to be sprayed with the solder flux instead of the solder paste, reducing an area occupied by the solder paste in a reflective cup and further reducing a size of the chip holder.

### BRIEF DESCRIPTION OF THE DRAWINGS

FIG. 1 is a schematic cross-sectional view of a vertically structured LED light-emitting chip provided according to a first embodiment of the present application;

FIG. 2 is a partially enlarged view of portion A in FIG. 1;

FIG. 3 is an enlarged schematic view of a partial area of the vertically structured LED light-emitting chip according to a second embodiment of the present application;

FIG. 4 is an enlarged schematic view of a partial area of the vertically structured LED light-emitting chip according to a third embodiment of the present application;

FIG. 5 is a schematic cross-sectional view of the vertically structured LED light-emitting chip according to a fourth embodiment of the present application;

FIG. 6 is a top view of another vertically structured LED light-emitting chip provided in the fourth embodiment of the present application;

FIG. 7 is a top view of another vertically structured LED light-emitting chip provided in a fifth embodiment of the present application; and

FIG. 8 is a schematic cross-sectional view of a light-emitting structure provided in the present application.

### DETAILED DESCRIPTION

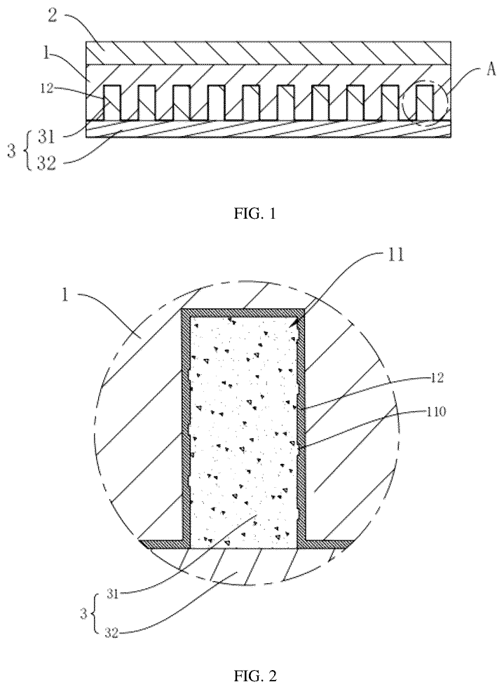

The present application is further described in detail below with reference to FIGS. 1-8.

A common application solution for an LED chip is to fix the LED chip inside a bracket. The LED chip is powered on to emit a light, and the bracket converges the light emitted by the LED chip and emits the converged light. The LED chip and the bracket are fixed by a conductive silver paste.

Specifically, in a chip structure of a related technology, the conductive silver paste is applied on a side of a substrate away from an epitaxial layer. When the LED chip operates, light may be generated by photons released when electrons and holes are combined in the epitaxial layer, during which the generated photons do not have a fixed direction. Therefore, a light emitting direction of the LED chip also diffuses throughout an entire space. It is detected that an existing chip structure does not have a high light utilization efficiency. Especially for the light in a red wavelength range and an ultraviolet wavelength range, a portion of the light irradiated towards a direction of the LED chip facing the bracket will be absorbed by the conductive silver paste. This is because when the light is incident on silver nanoparticles in the conductive silver paste, if a frequency of the incident light matches a vibration frequency of free electrons in the silver nanoparticles, a surface plasmon resonance (SPR) will be excited. This phenomenon will cause that the light at specific wavelengths is absorbed and scattered strongly by the silver nanoparticles.

The present application discloses a vertically structured LED light-emitting chip that can solve a problem of a low light utilization efficiency caused by the light absorption.

Referring to FIGS. 1-2, a vertically structured LED light-emitting chip provided in a first embodiment of the present application includes a substrate 1, an epitaxial layer 2 grown on a surface of the substrate 1, a reflective layer 12 formed on a side of the substrate away from the epitaxial layer 2, and conductive pastes 3 formed on a surface of the reflective layer 12.

A side of the substrate 1 is provided with a plurality of filling grooves 11 uniformly distributed thereon, a depth of each of the filling grooves 11 is less than or equal to a thickness of the substrate 1. In this embodiment, a cross-section of each of the filling grooves 11 is square, with a depth of 10-150 μm and a diameter of 10-500 μm.

The reflective layer 12 is provided on an inner wall of each of the filling grooves 11 and a surface of the side of the substrate 1 away from the epitaxial layer 2, and the reflective layer 12 has a material which can be selected as a specular silver. A bottom wall and a side wall of each of the filling grooves 11 are covered with the specular silver, and thus the light in various wavelength bands can be reflected at different angles, allowing the light to be emitted from a front of the chip, thereby improving the light utilization efficiency of the chip. The specular silver also has a good thermal conductivity, which can effectively conduct heat and reduce thermal accumulation within the chip.

The epitaxial layer 2 is grown on a side of the substrate 1 away from the filling grooves 11. The epitaxial layer 2 may include a buffer layer, a carrier injection layer, a light-emitting layer, a carrier diffusion layer and an epitaxial protective layer, which are all common techniques in the art and will not be repeated here.

The conductive pastes 3 includes a first conductive paste 31 filling the filling grooves 11 and a second conductive paste 32 provided on the side of the substrate 1 away from the epitaxial layer 2. The second conductive paste 32 and the first conductive paste 31 may form an integrated structure. The second conductive paste 32 has a thickness smaller than that of the substrate 1 and may completely cover the substrate 1.

The conductive paste 3 may be selected as a solder paste, and the thickness of the second conductive paste 32 can be selected as 1-5 μm. In this way, under a condition of satisfying subsequent conductivity with electrodes of the chips, short circuit between chips caused by overflow of the solder paste during reflow soldering can be reduced.

The conductive paste 3 may be used as a lower electrode of the vertically structured LED light-emitting chip. It can be understood that an upper electrode (not shown) is formed on a surface of the epitaxial layer 2 away from the substrate 1. When the upper electrode and the lower electrode are energized, the vertically structured LED light-emitting chip can operates.

An optional manufacturing method for the vertically structured LED light-emitting chip mentioned above includes:
B1: providing the substrate 1;
B2: growing the epitaxial layer 2 on a side surface of the substrate 1;
B3: thinning the side of the substrate 1 away from the epitaxial layer 2;
B4: spin-coating a layer of photoresist on a side of the thinned substrate 1;
B5: providing a mask plate, and placing the mask plate on a side of the photoresist away from the substrate 1, the mask plate is provided with a preset pattern and has a pattern area being opaque black and other area being transparent;
B6: controlling light to uniformly irradiate the photoresist through the mask plate, and the light in the pattern area is blocked by the mask plate and the photoresist in the pattern area does not change, and the photoresist in the area except the pattern area is crosslinked and cured.
B7: cleaning and removing the uncrosslinked photoresist by using a solution that reacts with the photoresist, so that the side of the substrate 1 away from the epitaxial layer 2 has a protruding three-dimensional pattern;
B8: performing a plasma etch on the side of the substrate 1 away from the epitaxial layer 2 by using plasma until the filling grooves 11 are formed on the substrate 1, and each of the filling grooves 11 has a height less than or equal to that of the substrate 1. Each of the filling grooves 11 has a depth of 10-150 μm and a diameter of 10-500 μm. Within the ranges of depth and diameter, the depth and diameter of each of the filling grooves 11 can also be maximized under a condition of meeting strength requirements of the substrate 1, thereby increasing an area for disposing the reflective layer 12 and increase a probability of a light reflection;
B9: evaporating the reflective layer 12 in the filling grooves 11; and
B10: blade-coating the conductive paste 3 on the side of the substrate 1 facing the filling grooves 11, the conductive paste 3 includes the first conductive paste 31 and the second conductive paste 32, the first conductive paste 31 is filled into the filling grooves 11, and the second conductive paste 32 covers the surface of the substrate 1.

An implementation principle of Embodiment 1 is:

In an assembly and packaging process of the vertically structured LED light-emitting chip in this embodiment, stable physical and electrical connections can be achieved by spraying a solder flux on a surface of the conductive paste 3 or on the bracket; followed by attaching the LED chip to a predetermined position so that the conductive paste 3 comes into contact with the solder flux; and then allowing the conductive paste 3 to be in a molten state through a reflow soldering and then to be cooled.

In an aspect, according to the above solution, it is not necessary to brush the conductive silver paste in the assembly of the LED chip, which reduces manufacturing difficulty and equipment requirements, and can improve a production efficiency. In another aspect, compared to a solution in related technologies in which the substrate or bracket is electrically connected to the chip through the conductive silver paste, the LED chip in this embodiment is more closely attached to the substrate, which can meet requirements of more lightweight design. Moreover, the conductive paste 3 is embedded in the filling grooves 11, which increases contact area between the conductive paste 3 and the substrate 1 and enhances curing strength compared to the substrate without the grooves.

From a usage perspective, when the LED chip is energized, the electrons in the epitaxial layer 2 move under the influence of an electric field, forming a current while also combining with holes to release the photons, which is macroscopically manifested as light emission. At this time, the light mainly primarily propagate in two directions, a portion of the light is directly emitted from the epitaxial layer 2, and has a direction similar to that in the related technologies; another portion is the light that is absorbed by the conductive silver paste in the related technologies, which in this embodiment is irradiated onto the reflective layer 12 and reflected by the reflective layer before being emitted.

In fact, the plurality of filling grooves 11 are provided in this embodiment, and the current enters the filling grooves 11 through the first conductive paste 31 distributed uniformly; after being conducted by the substrate 1, a plurality of electrodes are uniformly formed on a side of the epitaxial layer 2 facing the substrate 1. As a result, the current is uniformly distributed across the entire epitaxial layer 2. Therefore, the current can be fully utilized. Under a condition of a constant total current, the more uniform the current distribution, the greater the light emission intensity of the epitaxial layer 2, and the greater the overall light emission intensity exhibited on the LED chip.

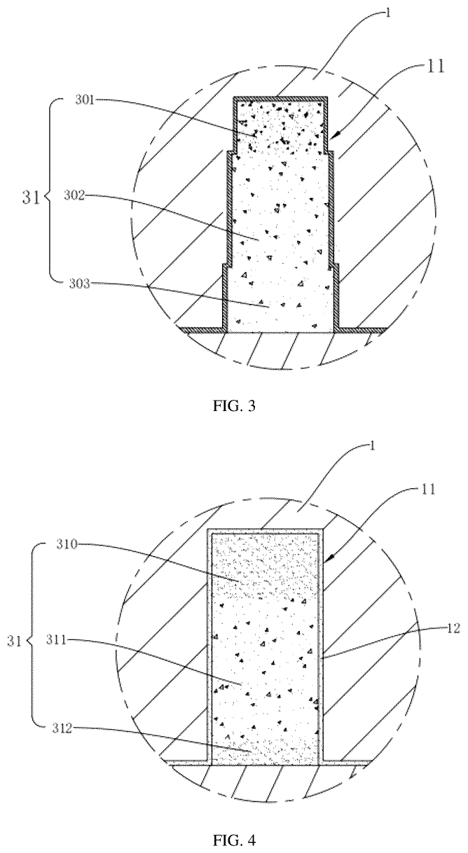

Referring to FIG. 3, which shows the vertically structured LED light-emitting chip provided in a second embodiment of the present application, the vertically structured LED light-emitting chip provided in the second embodiment is substantially the same as that in the first embodiment in addition to that: in this embodiment, the cross-section of each of the filling grooves 11 is in a stepped shape to facilitate a smooth filling of the conductive paste in the filling grooves 11, the first conductive paste 31 includes a first electrically conductive layer 301, a second electrically conductive layer 302, and a third electrically conductive layer 303. The third electrically conductive layer 303 is conductive paste on a surface layer close to an opening. From a bottom layer to the surface layer of the groove, the thermal conductivity gradually decreases while the conductivity gradually increases.

Specifically, in this embodiment, the first conductive layer 301 has an electrical conductivity range of (10⁴-10⁵ S/m) and a thermal conductivity range of (200-400 W/m·K); the second conductive layer 302 has an electrical conductivity range of (10⁵-10⁶ S/m) and the thermal conductivity range of (100-250 W/m·K); the third conductive layer 303 has an electrical conductivity range of (10⁶-10⁷ S/m) and the thermal conductivity range of (50-150 W/m·K).

More specifically, the first electrically conductive layer 301 may has compositions including: silver powder of 40-45 wt %, thermal conductive powder of 20-30 wt %, resin and solvent of 25-30 wt %, and adhesive of 5-10 wt %, and the first electrically conductive layer 301 may has a thickness of 20-40 microns. The thermal conductive powder may be copper powder or aluminum powder.

The second electrically conductive layer 302 may has compositions including: the silver powder of 50-55 wt %, the thermal conductive powder of 10-15 wt %, the resin and solvent of 25-30 wt %, and the adhesive of 5-10 wt %, and the second electrically conductive layer 302 may has a thickness of 30-60 microns.

The third electrically conductive layer 303 may has compositions including: the silver powder of 65-70 wt %, the resin and solvent of 20-25 wt %, and the adhesive of 5-10 wt %, and the third electrically conductive layer 303 may has a thickness of 50-100 microns.

In this embodiment, after the reflow soldering, the first electrically conductive layer 301 is used for filling to form the second electrically conductive layer 302 after being reflow soldered, the second electrically conductive layer 302 is used to form the third electrically conductive layer 303 after being reflow soldered and cured. The reflow soldering process of each layer ensures strong adhesion between electrically conductive layers. After the reflow soldering, the bonding between the layers becomes tighter, avoiding an interlayer delamination caused by thermal expansion and other reasons, and ensuring stability and reliability of the multi-layer structure.

In this embodiment, the filling grooves can be fully filled by dividing the conductive paste into three layers, and thus the conductivity can be ensured. The thermal conductivity and electrical conductivity of each of the layers are designed to gradually decrease and increase, respectively, from a bottom of the groove to a notch of the groove, achieving better thermal management and electrical performance. The electrically conductive layer at the notch of the groove provides a good electrical conductivity, while the electrically conductive layer at the bottom of the groove optimizes the thermal conductivity, and the electrically conductive layer in the middle may be used as a transitional layer for the thermal conductivity and the electrical conductivity. This design ensures that heat can be effectively conducted from high temperature areas to low temperature areas, avoiding local overheating and helping to improve a long-term reliability and stability of the device.

Referring to FIG. 4, which shows the vertically structured LED light-emitting chip provided in a third embodiment of the present application, the vertically structured LED light-emitting chip provided in the third embodiment is substantially the same as the first embodiment in addition to that: in this embodiment, the first conductive paste 31 includes:
a first conductive powder layer 310, filled at a bottom of each of the filling grooves 11;
a second conductive adhesive layer 311 formed on a surface of the first conductive powder layer 310; and
a third conductive powder layer 312, formed on a side of the second conductive adhesive layer 311 away from the first conductive powder layer 310.

Furthermore, a thickness of the second conductive adhesive layer 311 is greater than a thickness of the first conductive powder layer 310, the thickness of the second conductive adhesive layer 311 is greater than a thickness of the third conductive powder layer 312, and the thickness of the third conductive powder layer 312 is less than the thickness of the first conductive powder layer 310.

Each of the first conductive powder layer 310 and the third conductive powder layer 312 includes conductive particles or a mixture of electrically conductive particles and thermal conductive particles, and the electrically conductive particles may be any one of the copper powder and the silver powder.

The second conductive adhesive layer 311 has compositions including the silver powder of 50-55 wt %, the thermal conductive powder of 10-15 wt %, the resin and solvent of 25-30 wt %, and the adhesive of 5-10 wt %, and the second conductive adhesive layer 311 has a thickness of 30-60 microns.

The vertically structured LED light-emitting chip provided in this embodiment includes the first conductive paste 31 divided into three layers, and each of a bottom layer and a notch layer of the groove is the conductive powder layer, a middle layer between the bottom layer and the notch layer of the groove is the conductive adhesive layer. In this way, filling difficulty caused by a small diameter of each of the filling grooves 11, which may affect electrical performance of the light-emitting chip, can be avoided.

In this embodiment, the bottom of the groove is first filled with the conductive powder layer, which can be directly sprayed into the filling grooves 11 through a powder spraying technology. The middle layer is the conductive adhesive layer. In an aspect, the middle layer is served to seal the first conductive powder layer 310 and adhere the third conductive powder layer 312 due to adhesive property of the conductive adhesive. Thus, strong connections between the first conductive powder layer 310 and the second conductive adhesive layer 311, and between the second conductive adhesive layer 311 and the third conductive powder layer 312 can be ensured. That is to say, the third conductive powder layer 312 is sealed by the second conductive adhesive layer 311 and the second conductive paste 32. In another aspect, since the bottom layer of the groove is the conductive powder layer, and the thermal conductivity of the conductive powder layer is better than that of the conductive paste, and thus the heat generated by the photons in the epitaxial layer 2 can be quickly conducted to the second conductive adhesive layer 311, and then conducted to the outside layer by layer. A stress caused by thermal expansion while the chip is in operation can be absorbed by the second conductive adhesive layer 311 provided between the bottom and the notch of the groove, so as to avoid thermal damage to the chip.

When the reflective layer 12 includes the specular silver, and the grooves are only filled with the conductive adhesive, a distribution of conductive filler may be non-uniform, which results in a high local resistance. During a curing process, the conductive adhesive may also experience a decrease in the electrical conductivity due to settlement or non-uniform distribution. The conductive powder such as the silver powder has a high electrical conductivity and can directly contact the specular silver, forming an efficient conductive path and significantly reducing a contact resistance.

More preferably, the adhesive included in the second conductive paste 32 and the adhesive included in the second conductive adhesive layer 311 can be crosslinked during the reflow soldering, and thus bonding tightness can be enhanced. The third conductive powder layer 312 can better fill gaps formed by the reflow soldering during the reflow soldering, thereby improving the electrical conductivity of the chip.

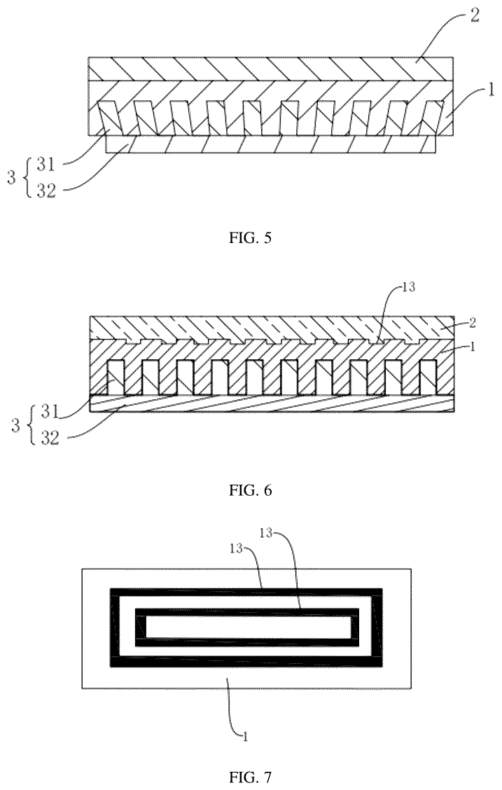

Referring to FIG. 5, which shows the vertically structured LED light-emitting chip provided in a fourth embodiment of the present application, the vertically structured LED light-emitting chip provided in the fourth embodiment is substantially the same as the first embodiment, in addition to that: in this embodiment, the filling grooves 11 gradually move away from a center of the substrate 1 as they penetrate deeper into the substrate 1. In other words, when the cross-section of each of the filling grooves 11 is taken in a plane parallel to the epitaxial layer 2, as a plane gradually approaches the epitaxial layer 2, the cross-sections of the filling grooves 11 are distributed uniformly, and distances between the respective filling grooves 11 increase gradually. A normal line of a bottom surface of each of the filling groove 11 deviates in a direction away from a center of the LED chip, when the light is irradiated from the epitaxial layer 2 to the reflective layer 12 at the bottom of each of the filling grooves 11, the light is reflected and deviated in the direction away from the light emitting direction of the LED chip, expanding a light emitting angle of the LED chip and ensuring sufficient light intensity over a larger range.

An orthographic projection of the second conductive paste 32 onto the substrate 1 is entirely contained within the substrate 1, and a dimension of the projection is smaller than that of the substrate 1. Preferably, an edge of an outermost filling groove 11 is inscribed within the orthographic projection of the second conductive paste 32.

It should be noted that the filling grooves 11 are not limited to circular, conical, or polygonal shapes, and shapes of the filling grooves 11 are not limited to a stretched body, and may also be a cone, a hexagonal pyramid or the like. When the filling grooves 11 are provided as cones, an effect of diffusing the light can be achieved.

Preferably, a microstructure 110 is further formed in a side wall of each of the filling grooves 11, which is connected to the filling groove 11. The first conductive paste 31 is embedded in the microstructure. In this way, a bonding strength between the conductive paste 3 and the substrate 1 can be enhanced, and a probability of accidental disconnection of the device due to external factors such as vibration is reduced. In addition, the current is more distributed, and the intensity of the output light is further increased while the total current remains constant.

The microstructure 110 can optionally be configured as a wetting microgroove, which is defined as a microscopic groove-shaped structure. The wetting microgroove extends spirally from an opening of each of the filling grooves 11 to the bottom thereof. By forming the microstructure 110 on the side wall of each of the filling grooves 11, a total internal reflection constraints can be disrupted, thereby enhancing the light scattering and extraction efficiency.

The implementation principle of the vertically structured LED light-emitting chip provided in the present application is that a dimension of the cross section of the cured conductive paste 3 parallel to the epitaxial layer 2 may be larger than an original dimension of the cross section of the conductive paste 3 before being cured parallel to the epitaxial layer 2, due to a compression from the chip and an effect of a surface tension during melting and curing process of the conductive paste 3. If the original dimension of the second conductive paste 32 is designed according to the substrate 1, some of the conductive paste 3 will overflow beyond the projection of the LED chip onto the substrate after assembly, which exists a risk of short circuiting with other elements. Therefore, the dimension of the second conductive paste 32 is reduced to ensure that the assembled conductive paste 3 is contained within the LED chip.

Due to the provision of the filling grooves 11 gradually dispersed along with the penetration into the substrate 1, the current received by the epitaxial layer 2 can be more dispersed and uniform under the condition that spacings between openings of the filling grooves 11 are unchanged, and the intensity of the output light can be further enhanced.

Referring to FIGS. 6-7 showing the vertically structured LED light-emitting chip provided in a fifth embodiment of the present application, the vertically structured LED light-emitting chip provided in the fifth embodiment is substantially the same as that in the first embodiment in addition to that: in this embodiment, referring to FIG. 6, a second surface of the substrate 1 opposite to a first surface is provided with a plurality of grooves 13, and projections of the grooves 13 onto the substrate 1 do not coincide with projections of the filling grooves 11 onto the substrate 1, and the epitaxial layer 2 is also formed in the grooves 13.

Referring to FIG. 7, the second surface of the substrate 1 opposite to the first surface is provided with the plurality of grooves 13 that are provided in a concentric manner, each of the grooves 13 is in a shape of a circular track, and the epitaxial layer 2 is also formed in the grooves 13.

The contact surface between the epitaxial layer 2 and the substrate 1 is increased through the grooves 13, and thus a stronger bond between the epitaxial layer 2 and the substrate 1 is ensured and a risk of separation and stripping is reduced.

The design of concentric circular track shaped grooves 13 optimizes an expansion path of the current and reduces a current crowding. According to this structure, the current can be distributed more uniformly throughout the entire epitaxial layer, and thus light emitting efficiency and reliability of the chip can be improved. A phenomenon of the current crowding usually occurs near an electrode injection point, resulting in excessively high local current density, which affects the light emitting efficiency and reliability of the chip. The design of concentric circular track shaped grooves 13 reduces an accumulation of the current in local areas by dispersing current paths. This structure allows the current to flow more uniformly to various parts of the chip, thereby reducing a difference in current density.

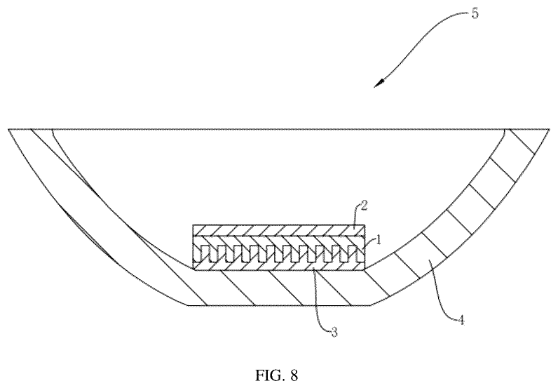

Referring to FIG. 8, the present application further discloses a light-emitting structure. The light-emitting structure includes a chip holder 4 and an LED chip, the LED chip is the vertically structured LED light-emitting chip as mentioned above. The chip holder 4 is provided with external electrodes, and the solder flux is formed on the external electrodes. The conductive paste 3 on the LED chip is electrically connected to the electrodes on the chip holder 4 through the solder flux.

In summary, according to the light-emitting structure and vertically structured LED light-emitting chip provided in the present application, due to the filling grooves 11 are provided in the substrate 1, the reflective layer 12 is formed in the filling grooves 11, and then the conductive paste 3 is filled in the filling grooves 11. The light generated in the epitaxial layer 2 can be reflected by the reflective layer 12, and thus an absorption of the light incident on the substrate 1 can be avoided. The current injection path can be optimized by providing the conductive paste in the filling grooves, making the current more uniformly distributed on the entire surface of the chip. This design reduces the phenomenon of the current crowding and improves an current expansion efficiency. The conductive paste at the bottom layer of the groove has a high thermal conductivity of (200-400 W/m·K), which effectively conducts the heat and reduces the thermal accumulation, thereby enhancing thermal dissipation performance of the chip.

The above are the preferred embodiments of the present application, which are not intended to limit the protection scope of the present application. Therefore, all equivalent changes made according to the structure, shape and principle of the present application should be covered within the protection scope of the present application.

### LIST OF REFERENCE SIGNS

1 substrate
11 filling groove
12 reflective layer
2 epitaxial layer
3 conductive paste
31 first conductive paste
32 second conductive paste
4 chip holder
310 first conductive powder layer
311 second conductive adhesive layer
312 third conductive powder layer
5 light-emitting structure
301 first electrically conductive layer
303 third electrically conductive layer
302 second electrically conductive layer
13 groove
110 microstructure

What is claimed is:

1. A vertically structured light-emitting diode (LED) light-emitting chip, comprising:
a substrate, wherein a first surface of the substrate is provided with a plurality of filling grooves, a depth of each of the plurality of filling grooves is less than or equal to a thickness of the substrate, and a reflective layer is formed on a peripheral wall and a bottom surface of each of the plurality of filling grooves;
an epitaxial layer, formed on a side of the substrate away from the plurality of filling grooves; and
a conductive paste, at least provided in the plurality of filling grooves.

2. The vertically structured LED light-emitting chip according to claim 1, wherein a second surface of the substrate opposite to the first surface is provided with a plurality of grooves, projections of the plurality of grooves onto the substrate are non-coincident with projections of the plurality of filling grooves onto the substrate, and the epitaxial layer is further formed in the plurality of grooves.

3. The vertically structured LED light-emitting chip according to claim 1, wherein a second surface of the substrate opposite to the first surface is provided with a plurality of grooves, the plurality of grooves are provided in a concentric manner, each of the plurality of grooves is in a shape of a circular track, and the epitaxial layer is further formed in the plurality of grooves.

4. The vertically structured LED light-emitting chip according to claim 1, wherein each of the plurality of filling grooves is one of cylindrical, truncated conical, hexagonal prism, or triangular pyramid shaped, a central axis of each of the plurality of filling grooves is perpendicular to the epitaxial layer, and each of the plurality of filling grooves has a depth of 10-150 μm and a diameter of 10-500 μm.

5. The vertically structured LED light-emitting chip according to claim 4, wherein the plurality of filling grooves are uniformly distributed in the substrate, the central axis of each of the plurality of filling grooves is inclined relative to a central axis of the substrate, cross sections of the plurality of filling grooves taken in any cross section parallel to the epitaxial layer are uniformly distributed, the peripheral wall of each of the plurality of filling grooves is further provided with a microstructure, and the microstructure is provided as a wetting microgroove extending spirally towards a bottom of a corresponding one of the plurality of filling grooves.

6. The vertically structured LED light-emitting chip according to claim 1, wherein the conductive paste comprises a first conductive paste filled in each of the plurality of filling grooves and a second conductive paste provided on a surface of the substrate away from the epitaxial layer, and the second conductive paste has a thickness of 1-5 μm.

7. The vertically structured LED light-emitting chip according to claim 6, wherein a cross section of each of the plurality of filling grooves is in a stepped shape, the first conductive paste comprises a first electrically conductive layer, a second electrically conductive layer, and a third electrically conductive layer sequentially stacked in each of the plurality of filling grooves, the first electrically conductive layer has an electrical conductivity range of 10⁴-10⁵ S/m and a thermal conductivity range of 200-400 W/m·K, the second electrically conductive layer has an electrical conductivity range of 10⁵-10⁶ S/m and a thermal conductivity range of 100-250 W/m·K, and the third electrically conductive layer has an electrical conductivity range of 10⁶-10⁷ S/m and a thermal conductivity range of 50-150 W/m·K.

8. The vertically structured LED light-emitting chip according to claim 7, wherein the first electrically conductive layer has a composition comprising silver powder of 40-45 wt %, thermal conductive powder of 20-30 wt %, resin and solvent of 25-30 wt %, and adhesive of 5-10 wt %, and has a thickness of 20-40 microns;
the second electrically conductive layer has a composition comprising the silver powder of 50-55 wt %, the thermal conductive powder of 10-15 wt %, the resin and solvent of 25-30 wt %, and the adhesive of 5-10 wt %, and has a thickness of 30-60 microns; and
the third electrically conductive layer has a composition comprising the silver powder of 65-70 wt %, the resin and solvent of 20-25 wt %, and the adhesive of 5-10 wt %, and has a thickness of 50-100 microns.

9. The vertically structured LED light-emitting chip according to claim 6, wherein the first conductive paste comprises:
a first conductive powder layer filled at a bottom of each of the plurality of filling grooves;
a second conductive adhesive layer formed on a surface of the first conductive powder layer; and
a third conductive powder layer formed on a side of the second conductive adhesive layer away from the first conductive powder layer.

10. The vertically structured LED light-emitting chip according to claim 9, wherein a thickness of the second conductive adhesive layer is greater than a thickness of the first conductive powder layer, and the thickness of the second conductive adhesive layer is greater than a thickness of the third conductive powder layer.

11. A light-emitting structure, comprising:
a chip holder comprising external electrodes provided on the chip holder, and solder flux is formed on the external electrodes; and
an LED chip, which is the vertically structured LED light-emitting chip according to claim 7, wherein the LED chip is electrically connected to the external electrodes on the chip holder through the solder flux.

12. A light-emitting structure, comprising:
a chip holder comprising external electrodes provided on the chip holder, and solder flux is formed on the external electrodes; and
an LED chip, which is the vertically structured LED light-emitting chip according to claim 9, wherein the LED chip is electrically connected to the external electrodes on the chip holder through the solder flux.
